(19) United States
(12) Patent Application Publication
(10) Pub. No.: US 2023/0359917 A1
(43) Pub. Date: Nov. 9, 2023

(54) MODULAR QUANTUM CHIP DESIGN WITH OVERLAPPING CONNECTION

(71) Applicant: INTERNATIONAL BUSINESS MACHINES CORPORATION, ARMONK, NY (US)

(72) Inventors: David Abraham, Croton, NY (US); John Michael Cotte, New Fairfield, CT (US); Muir Kumph, Croton on Hudson, NY (US)

(21) Appl. No.: 17/740,279

(22) Filed: May 9, 2022

(51) Int. Cl. G06N 10/40

(52) U.S. Cl. CPC G06N 10/40

(57) ABSTRACT

A quantum computing (QC) chip module includes an interposer chip having a footprint. A qubit chip bump is bonded to the interposer chip and arranged so that the qubit chip extends beyond the footprint of the interposer chip. The interposer chip extends beyond an edge of the qubit chip. A wiring harness is connected to the interposer chip.

### BACKGROUND

### Technical Field

The present disclosure generally relates to quantum computing, and more particularly, to a quantum computing chip design.

### Description of the Related Art

Superconducting quantum computing is an implementation of a quantum computer in superconducting electronic circuits. Quantum computation studies the application of quantum phenomena for information processing and communication. Various models of quantum computation exist, and the most popular models include the concepts of qubits and quantum gates. A qubit is a generalization of a bit that has two possible states, but can be in a quantum superposition of both states. A quantum gate is a generalization of a logic gate, however the quantum gate describes the transformation that one or more qubits will experience after the gate is applied on them, given their initial state. Various components, such as low-noise amplifiers, that may operate in different thermal isolation stages, can be used to communicate with qubits. Many quantum phenomena, such as superposition and entanglement, do not have analogs in the world of classical computing and therefore may involve special structures, techniques, and materials.

Quantum computing will involve large numbers of qubits to achieve the potential that has been suggested by persons of skill in the art. Currently, most existing silicon-based devices are larger and larger versions of the original smaller devices, e.g., all qubits are fabricated on a single chip. Once the qubit count exceeds something on order of about one thousand, it becomes difficult or impossible to fabricate such a monolithic device, both because of the wafer sizes required as well as practical concerns, such as tool availability or yield issues. Thus, modular fabrication methods are of interest with a focus on tightly packed chips to facilitate maintaining high quality bus connections between modules.

### SUMMARY

According to one embodiment, a quantum computing (QC) chip module includes an interposer chip having a footprint. A qubit chip bump is bonded to the interposer chip and arranged so that the qubit chip extends beyond the footprint of the interposer chip. The interposer chip extends beyond an edge of the qubit chip, and a wiring harness is connected to the interposer chip. The construction enables the overhang of the qubit chip from the interposer to form a capacitively coupled bus between neighboring qubit chips.

In one embodiment, the wiring harness comprises a superconducting flexible cable. The qubit chip is controlled and read by electrical signals in the superconducting flexible cable. The uses of the superconducting cable minimizes the loss of heat and electric signals.

According to one embodiment, a quantum computing (QC) chip module assembly includes a plurality of QC chip modules connected in a row. Each QC chip module includes an interposer chip having a footprint. A qubit chip is bump bonded to the interposer chip and arranged so that the qubit chip extends beyond the footprint of the interposer chip. The interposer chip extends beyond an edge of the qubit chip. A wiring harness is connected to the interposer chip, the wiring harness including a superconducting flexible cable. The qubit chip is controlled and read by electrical signals in the superconducting flexible cable. The assembly provides enhanced dimensional accuracy by using the edge of the interposers to positions the modules with respect to each other.

In one embodiment, the plurality of QC modules include the qubit chip, interposer chipper chip, and wiring harness arranged in an L-shaped geometry. The L-shaped geometry permit the arrangement of the qubit chip to overhang to a neighboring module, to facilitate a capacitive coupling bus between the neighboring qubit chips.

In one embodiment, in each QC module the wiring harness is attached on two areas of the interposer chip to form a T-shaped geometry with the qubit chip arranged on the interposer chip. An increase amount of qubits can be arranged on the interposer with a connection of the wiring harness on two areas of the interposer chip.

In one embodiment, a gap between the qubit chip and the interposer chip is defined by a final bump height of the bump bonds that connect the qubit chip to the interposer chip, and is the same as a gap between the qubit chip and the interposer gap within any module of the plurality of QC chip modules. Having the “same” bump heights provides for a more accurate construction of the components of the QC modules.

According to one embodiment, a method of constructing a quantum computing (QC) chip module assembly includes the operations of: connecting a plurality of QC chip modules connected in a row. Each QC chip module includes an interposer chip having a footprint, a qubit chip bump bonded to the interposer chip and arranged so that the qubit chip extends beyond the footprint of the interposer chip. The interposer chip extends beyond an edge of the qubit chip. A wiring harness is connected to the interposer chip, the wiring harness including a superconducting flexible cable. The qubit chip is controlled and read by electrical signals in the superconducting flexible cable. The method permits the qubit chips to overhang to a neighboring module and create a capacitive coupling with the neighboring QC module.

In one embodiment, the method further includes arranging the qubit chip, the interposer chipper chip, and the wiring harness in an L-shaped geometry. The L-shaped geometry facilities arranging multiple QC modules together and creating a capacitively-coupled bus.

In one embodiment, in each QC module, the wiring harness is attached on two areas of the interposer chip to form a T-shaped geometry with the qubit chip arranged on the interposer chip. The T-shaped geometry more than doubles the number of qubits that may be connected to the interposer, allowing for larger and a denser circuitry.

In one embodiment, the method further includes defining a gap between the qubit chip and the interposer chip by a final bump height of the bump bonds that connect the qubit chip to the interposer chip. The defined gap is the same as a gap between the qubit chip and the interposer gap within any module of the plurality of QC modules. This method provides for a more uniform and dimensionally accurate construction.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition to or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a top view of a single quantum computing module and a quantum computing module assembly having a substantially L-shaped geometry, consistent with an illustrative embodiment.

FIG. 2 illustrates a top view of a single quantum computing module and a quantum computing module assembly having a substantially T-shaped geometry, consistent with an illustrative embodiment.

FIG. 3 illustrates an arrangement of a vertical gap between a cantilevered qubit chip and the neighboring interposer, consistent with an illustrative embodiment.

FIG. 4 illustrates a coupling scheme in which qubits are coupled to a neighboring qubit on a next qubit chip, consistent with an illustrative embodiment.

FIG. 5 illustrates two types of rigid backers used to reduce an inter-module gap between one qubit chip and a neighboring interposer, consistent with an illustrative embodiment.

FIG. 6 illustrates a cantilevered gap with controlled downstops, consistent with an illustrative embodiment.

FIG. 7 illustrates the adjustment of solder ball height through the use of under bump metallurgy, consistent with an illustrative embodiment.

FIG. 8 is a graph of a bus length to capacitance calculated between chips, consistent with an illustrative embodiment.

### DETAILED DESCRIPTION

### Overview

In the following detailed description, numerous specific details are set forth by way of examples to provide a thorough understanding of the relevant teachings. However, it should be understood that the present teachings may be practiced without such details. In other instances, well-known methods, procedures, components, and/or circuitry have been described at a relatively high level, without detail, to avoid unnecessarily obscuring aspects of the present teachings. It is to be understood that the present disclosure is not limited to the depictions in the drawings, as there may be fewer elements or more elements than shown and described.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

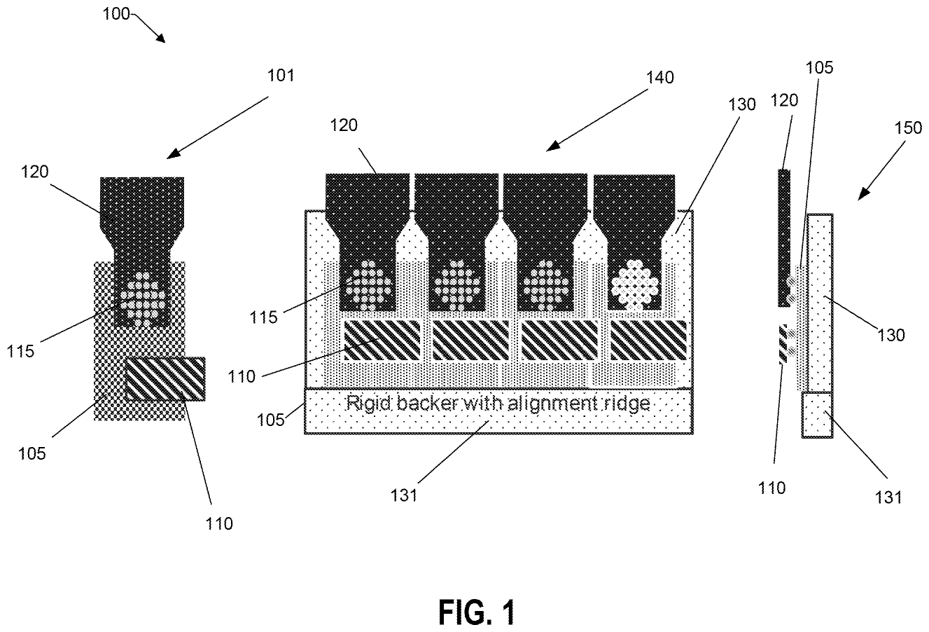

FIG. 1 illustrates a top view 100 of a single quantum computing module 101 and a quantum computing module assembly 140 having a substantially L-shaped geometry, consistent with an illustrative embodiment. The quantum computing module 101 includes an interposer 105 with a qubit chip 110 thereon and a wiring harness 120 that is attached to the interposer 105 by solder bump bonds 115. The qubit chip 110 extends to the right beyond the interposer. The interposer 105 extends substantially vertically from the qubit chip 110. The quantum computing module 101 may be controlled and read by electrical connections in a flexible cable of the flexible wiring harness 120. In one embodiment, the flexible wiring harness 120 may be a superconducting flexible cable to minimize heat loss and electrical signal loss.

The quantum computing module assembly 140 includes a plurality of the quantum computer modules 101 that are connected by arrangement in a row. It is to be understood that although four quantum computing modules 101 are shown in the quantum computing module assembly 140, there can be more modules 101 connected than four, or fewer modules 101 than four. In this embodiment, the overhanging qubit chips 110 are spaced above the neighboring interposer to the right. This overhang may be used to create a capacitively-coupled bus between neighboring qubit chips. A side view 150 of the assembled module is also shown, where the qubit chip 110 and the flexible warning harness 120 are shown arranged on the interposer 105, and on a rigid backer 130 that may have an alignment ridge 131. Through precision dicing of the interposer 105 and qubit chips 110 along with precise bonding with an accuracy of a few micrometers enables using the edge of the interposers to position the modules 101 with respect to each and to an alignment edge 131 built into a rigid backer 130.

Additional features of the quantum computing modules of the present disclosure are disclosed herein.

### Example Embodiments

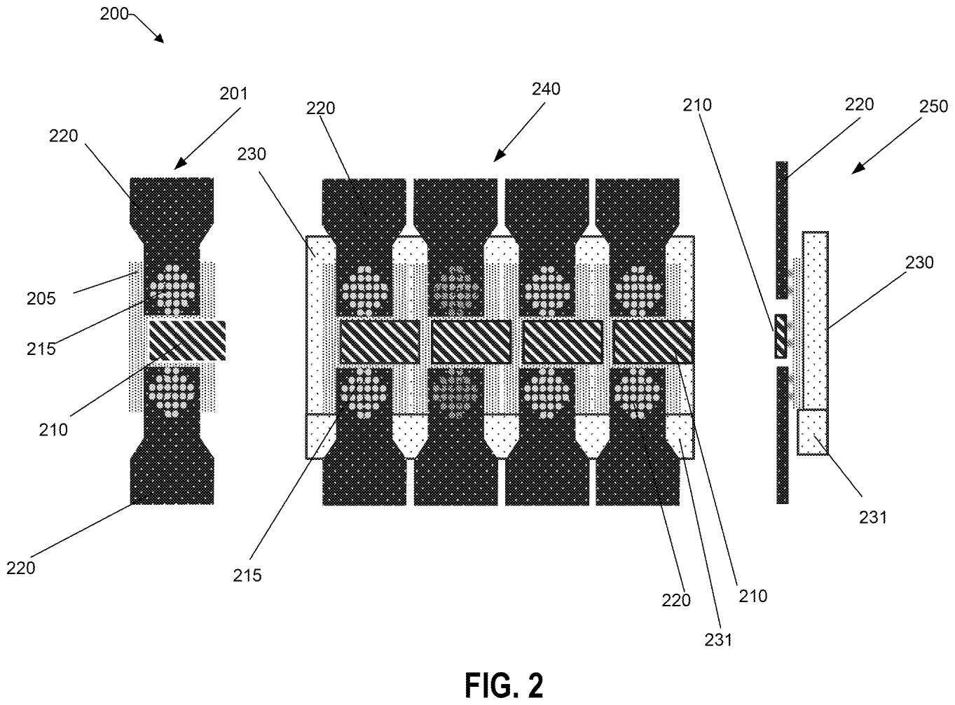

FIG. 2 illustrates a top view 200 of a single quantum computing module 201 and a quantum computing module assembly 240 having a substantially T-shaped geometry, consistent with an illustrative embodiment. In the example of FIG. 2, the flexible wiring harness 220 may be connected to two sides of the interposer 205. The arrangement of the qubit chip 210 and wiring harness 220 as shown may provide twice as many electrical connections as compared to the L-shaped module 140 of FIG. 1. The solder bumps 215 and the arrangement of the rigid backer 230 with a ridge 231 are also shown in the side view of the assembly.

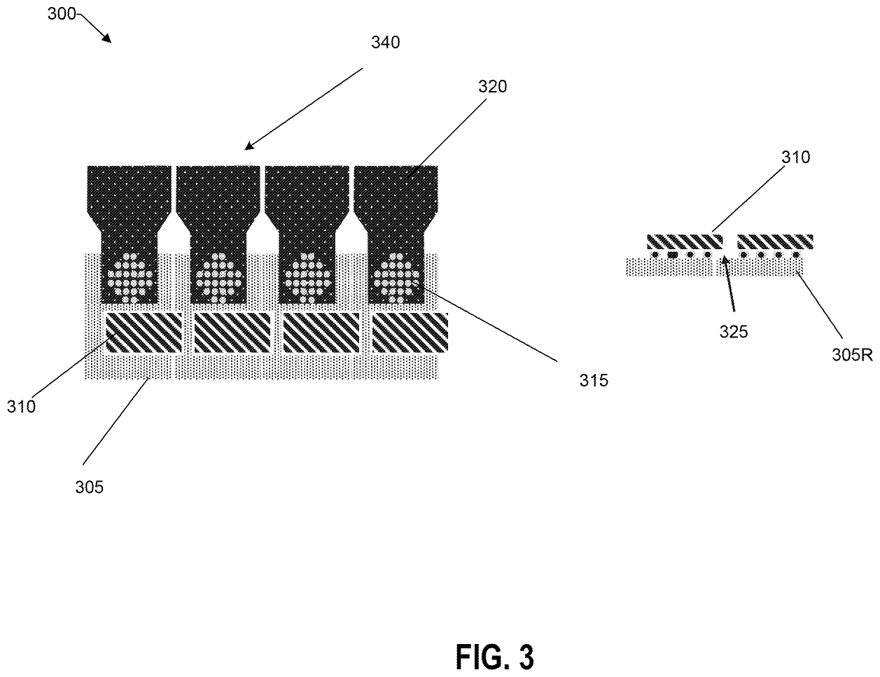

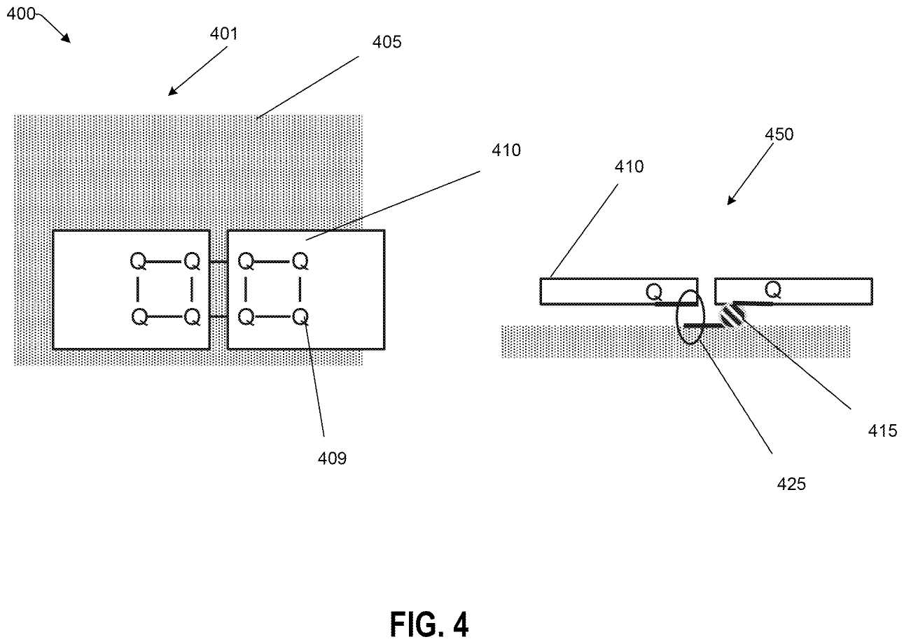

FIG. 3 illustrates an arrangement 300 of an assembly 340 of quantum computing modules having a vertical gap 325 between a cantilevered qubit chip 310 and the neighboring interposers 305, consistent with an illustrative embodiment. The view shows the vertical gap 325 between the cantilevered qubit chip 310 and the neighboring right interposer 305R. The solder bumps 315 are used to join the qubit chip 310 to the interposer chip 305. The bumps 315 may be selected from a variety of constructions, including but not in any way limited to: indium, indium alloys such as InSn, lead-based alloys, SnAuCu, etc., which are used to join the qubit chip 310 to the interposer chip 305. The gap 325 between the qubit chip 310 and the interposer chip 305 is defined by the final bump height, and is the same as the qubit-interposer gap within any module. Details of the qubit coupling are shown with reference to FIG. 4.

FIG. 4 illustrates a coupling scheme 400 in which qubits 409 on a qubit chip 410 of an assembly 401 are coupled to a neighboring qubit on a next qubit chip, consistent with an illustrative embodiment. The qubits 409 are placed on the bottom surface of the qubit chip 410 as in other embodiments. A front view 450 of the assembly is also shown. On the right hand edge, qubit buses will capacitively couple across the gap between the qubit 409 and a neighboring interposer 405 (in the region of the oval 425), then up through a superconducting bump 415 to a neighboring qubit on the next qubit chip. An equivalent coupling scheme may use inductive coupling instead of capacitive coupling. The dark black lines indicate superconducting metal traces and pads.

In an embodiment, the qubit chips 410 and the interposer chips 405 such as shown in FIG. 4 may have through-silicon vias (TSVs) for mode protection and isolation, and the interposer additionally uses the TSVs for signal transmission to the multilevel wiring layers on the backside of the thinned interposer chip 405.

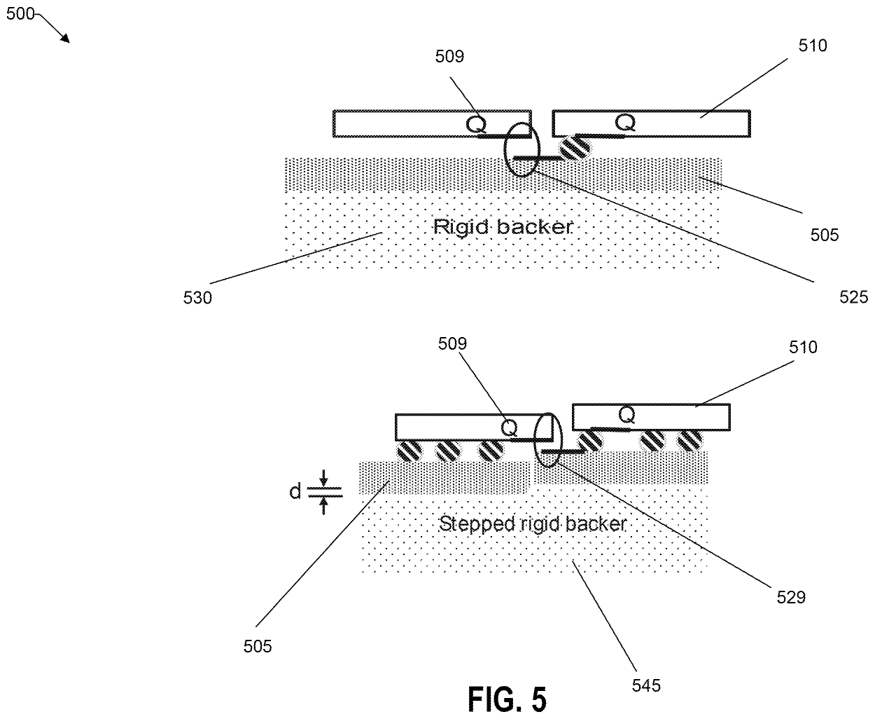

FIG. 5 illustrates two types of rigid backers 500 used to reduce an inter-module gap between one qubit chip and a neighboring interposer, consistent with an illustrative embodiment. In the case where the gap between qubit and interposer chips (defined by the bump bonds) is larger than desired (e.g., if the gap is on order 50 microns), then a controlled reduction of the gap between the qubit chip and the adjacent interposer may be performed.

The controlled reduction of the gap is accomplished by using a flat rigid backer 530 to hold all of the modules. The flat rigid backer 530 results in an inter-module gap 525 (e.g., between one qubit chip 510 with qubit 509 and the neighboring interposer 505) which is the same as the intra-module bump gap. Alternatively, a stepped rigid backer 545 may be used. The stepped rigid backer 545 is stepped by an amount “d”. The result is that the inter-module gap 529 using the stepped rigid baker 545 is reduced from the nominal by the amount d. For example, with a 50 micron bump-defined gap, and a step height ‘d’ in the backer of 40 microns, the inter-module gap would be 10 microns. Note that the stepped backer 545 may be stepped multiple times to connect several such modules, each with reduced inter-module gaps.

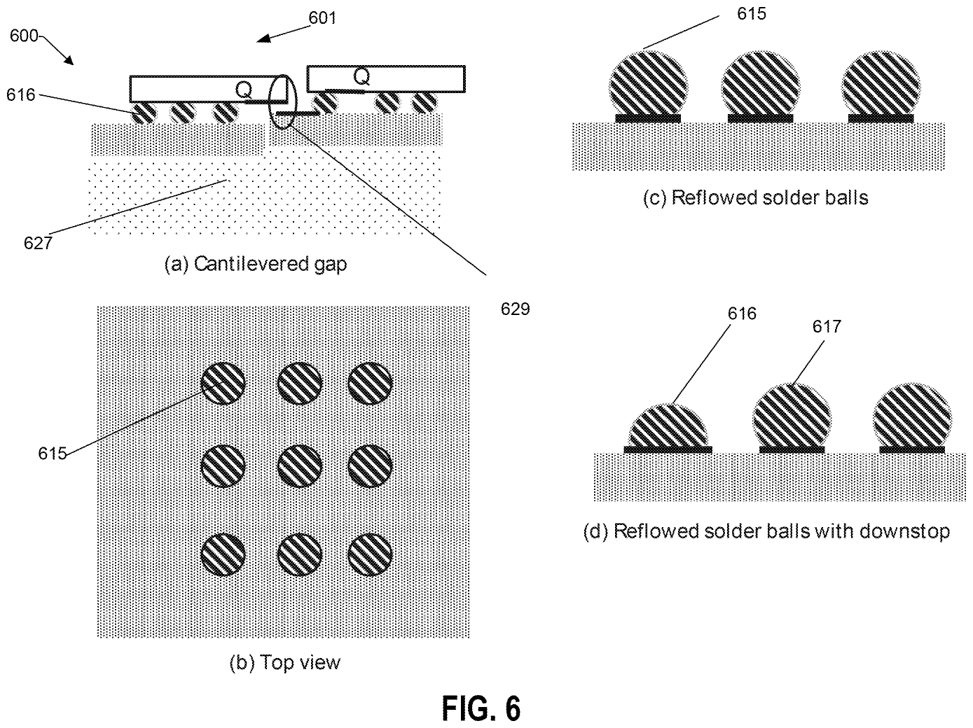

FIG. 6 illustrates a module assembly 600 having a cantilevered gap 601 with controlled downstops 616, 617, consistent with an illustrative embodiment. The cantilevered gap 629 achieved by using the stepped backer plate 627 effectively reduces the inter-module gap. However, this reduced gap may vary depending on the control of the bump-defined intra-module gap as well as machining tolerances in fabrication of the backer plate 627. To address the gap-reduction, an operation of creating controlled downstops on the interposers is described. While the use of downstops using micromachined silicon is known in some disciplines, the present solution offers the advantage of simplicity and ease of fabrication. The interposer wafer 605 is fabricated using controlled volumes of solder that are placed onto an under-bump metallurgy region as shown to the left. The circles 615 represent the under-bump metallization (UBM) films and in this case topped by gold. After reflow, the bump forms a truncated sphere 616, 617 of solder with the bottom of the solder ball flowing to the perimeter of the UBM. By adjusting the diameter of select UBM patches or the amount of solder present or both, much lower solder regions can be made and will act as standoffs for the neighboring module. In the mechanical arrangement, the interposers 605 will be pushed down onto the backer 627, and the qubit chips 610 will be pressed lightly down onto the rigid solder downstops 616, 617.

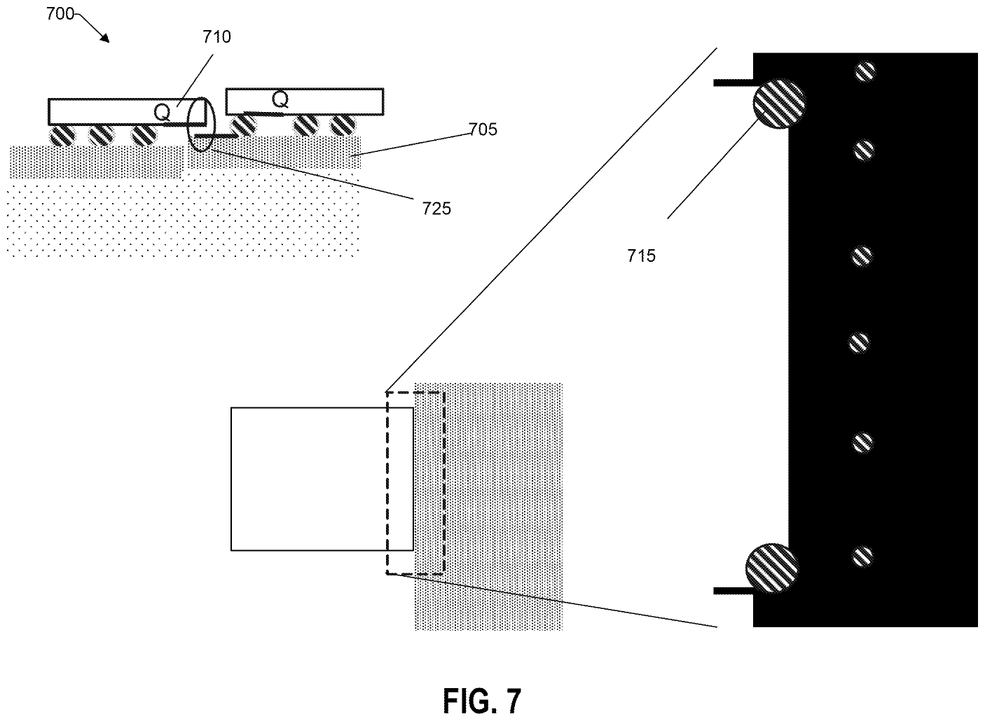

FIG. 7 illustrates the adjustment of solder ball height through the use of under bump metallurgy, consistent with an illustrative embodiment. Variable diameter UBMs may be used to adjust the gap between qubit chips and interposers. Larger UBM regions 715 provide lower solder standoffs. The gap 725 will be reduced between a qubit chip 710 and an adjacent interposer 705 will be reduced. Solder regions with much lower solder height will be relatively incompressible and will therefore serve as a mechanical downstop.

The standoff UBM size may depend on the details but simple calculations suggests that the standoff UBM may be in the range 400-700 um diameter to achieve 5 um height.

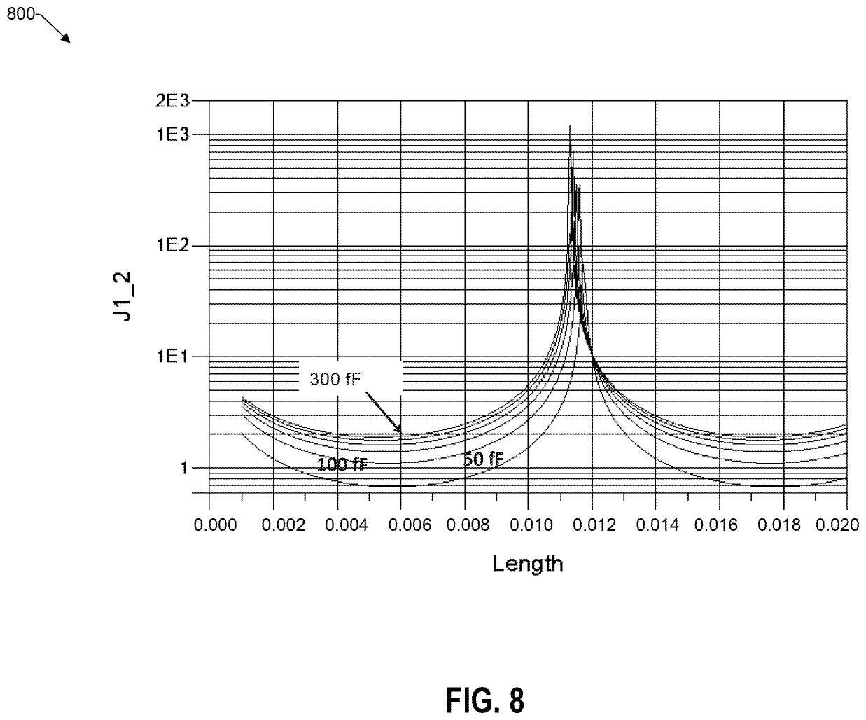

FIG. 8 is a graph of a qubit bus length to provide a coupling capacitance calculated between chips, consistent with an illustrative embodiment. The graph suggests that a large capacitance between chips is probably likely to use an increasing number of qubits. For example, to achieve 200 fF with a 5 micron gap a circular pad having a diameter of 380 microns would be recommended which is on the edge of practical. Further optimization (larger coupling capacitors at the qubits, for example) will be explored.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

The diagrams in the figures herein illustrate the architecture, functionality, and operation of possible implementations according to various embodiments of the present disclosure.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A quantum computing (QC) chip module comprising:
an interposer chip having a footprint;
a qubit chip bump bonded to the interposer chip and arranged so that the qubit chip extends beyond the footprint of the interposer chip, wherein the interposer chip extends beyond an edge of the qubit chip; and
a wiring harness connected to the interposer chip.

2. The QC chip module according to claim 1, wherein:
the wiring harness comprises a superconducting flexible cable; and
the qubit chip is controlled and read by electrical signals in the superconducting flexible cable.

3. The QC chip module according to claim 2, wherein a gap between the qubit chip and the interposer chip is defined by a final bump height of the bump bonds that connect the qubit chip to the interposer chip.

4. The QC chip module according to claim 3, wherein:
the qubit chip extends to horizontally beyond the interposer; and
the interposer extends substantially vertically from the qubit chip.

5. A quantum computing (QC) chip module assembly comprising:
a plurality of QC chip modules connected in a row, each QC chip module comprising:
an interposer chip having a footprint;
a qubit chip bump bonded to the interposer chip and arranged so that the qubit chip extends beyond the footprint of the interposer chip, wherein the interposer chip extends beyond an edge of the qubit chip; and
a wiring harness connected to the interposer chip,
wherein:
the wiring harness includes a superconducting flexible cable;
the qubit chip is controlled and read by electrical signals in the superconducting flexible cable.

6. The QC chip module assembly of claim 5, wherein the plurality of QC modules have the qubit chip, the interposer chipper chip, and the wiring harness arranged in an L-shaped geometry.

7. The QC chip module assembly of claim 5, wherein in each QC chip module the wiring harness is attached on two areas of the interposer chip to form a T-shaped geometry with the qubit chip arranged on the interposer chip.

8. The QC chip module assembly according to claim 5, wherein a gap between the qubit chip and the interposer chip is defined by a final bump height of the bump bonds that connect the qubit chip to the interposer chip, and is the same size as a gap between the qubit chip and the interposer gap within any module of the plurality of QC chip modules.

9. The QC chip module assembly of claim 5, wherein the plurality of QC chip modules are arranged in a tiled formation to form an air-gapped connection between the qubit chip of a first QC chip module and the interposer chip of a neighboring QC chip module.

10. The QC chip module assembly of claim 5, wherein the plurality of QC chip modules are arranged on a rigid backer.

11. The QC chip module assembly of claim 10, wherein the rigid backer includes an alignment ridge to facilitate an in-plane alignment of the plurality of QC chip modules.

12. The QC chip module assembly of claim device of claim 10, wherein the rigid backer includes a stair-step to raise each subsequently arranged QC chip module by a fixed height compared to a previously arranged module.

13. The QC chip module assembly of claim 10, wherein the interposer chip includes built-in standoffs to maintain a substantially constant gap between the interposer chip of a first QC chip module and the qubit chip of a neighboring QC module of the plurality of QC chip modules.

14. The QC chip module assembly of claim 10, wherein:
the rigid backer holds all the plurality of QC modules; and
an inter-module gap between one qubit chip and a neighboring interposer is the same as an intra-module bump gap.

15. The QC chip module assembly of claim 10, wherein a coupling between qubit chips on neighboring QC modules comprises a capacitive coupling across an air gap between the neighboring QC modules.

16. The QC chip module assembly of claim 10, wherein a coupling between qubit chips on neighboring QC modules comprises an inductive coupling between the neighboring QC modules.

17. A method of constructing a quantum computing (QC) chip module assembly, comprising:
connecting a plurality of QC chip modules connected in a row, wherein:
each QC chip module includes an interposer chip having a footprint, a qubit chip bump bonded to the interposer chip and arranged so that the qubit chip extends beyond the footprint of the interposer chip; and
the interposer chip extends beyond an edge of the qubit chip;
connecting a wiring harness connected to the interposer chip, wherein the wiring harness includes a superconducting flexible cable; and
controlling and reading the qubit chip by electrical signals in the superconducting flexible cable.

18. The method according to claim 17, further comprising arranging the qubit chip, the interposer chipper chip, and the wiring harness in an L-shaped geometry.

19. The method according to claim 17, wherein in each QC module the wiring harness is attached on two areas of the interposer chip to form a T-shaped geometry with the qubit chip arranged on the interposer chip.

20. The method according to claim 17, further comprising defining a gap between the qubit chip and the interposer chip by a final bump height of the bump bonds that connect the qubit chip to the interposer chip, wherein the defined gap is the same as a gap between the qubit chip and the interposer within any module of the plurality of QC modules.

21. The method according to claim 17, further comprising arranging the plurality of QC modules in a tiled formation to form an air-gapped connection between the qubit chip of a first QC chip module and the interposer chip of a neighboring QC chip module.

22. The method according to claim 17, further comprising arranging the plurality of QC chip modules on a rigid backer.

23. The method of claim 22, further comprising an alignment ridge to the rigid backer to facilitate an in-plane alignment of the plurality of QC chip modules.

24. The method of claim 22, further comprising a stair-step in the rigid backer to raise each subsequently arranged QC module by a fixed height compared to a previously arranged QC module.

25. The method of claim 24, further comprising:
fabricating the interposer chip using controlled volumes of solder placed onto an under-bump metallurgy (UBM) region; and
reflowing the solder bumps into a truncated sphere, with a bottom of the solder ball flowing to the perimeter of the UBM region.
